(19) United States
(12) Patent Application Publication
(10) Pub. No.: US 2026/0190483 A1
(43) Pub. Date: Jul. 2, 2026

(54) DISPLAY DEVICE

(71) Applicant: LG Display Co., Ltd., Seoul (KR)

(72) Inventors: Jun Ho LEE, Paju-si (KR); Jung Yul YANG, Paju-si (KR); Dae Hwan KIM, Paju-si (KR)

(73) Assignee: LG Display Co., Ltd., Seoul (KR)

(21) Appl. No.: 19/390,031

(22) Filed: Nov. 14, 2025

(30) Foreign Application Priority Data
Dec. 27, 2024 (KR) 10-2024-0198936

(51) Int. Cl. H10D 86/40; H10D 86/01

(52) U.S. Cl. CPC H10D 86/423; H10D 86/0221

(57) ABSTRACT

A display device is disclosed. The display device includes a substrate and a gate driver configured to supply a scan signal to a gate line. The gate driver includes a pull-up transistor and a pull-down transistor, with at least one of the transistors including a plurality of thin film transistors connected in parallel. These thin film transistors include source electrodes, drain electrodes, a common gate electrode, and a common active layer. The common gate electrode and the common active layer extend in a first direction, while the source and drain electrodes are disposed on the common active layer and spaced apart from the common gate electrode in a second direction crossing the first direction. The common active layer includes doped regions doped with a dopant and undoped regions not doped with the dopant. The doped regions and the undoped regions alternate as the common active layer extends in the first direction. This structure enables compact integration and efficient driving of the scan signal.

### CROSS-REFERENCE TO RELATED APPLICATION(S)

This application claims the benefit of Korean Patent Application No. 10-2024-0198936, filed on Dec. 27, 2024, which is hereby incorporated by reference as if fully set forth herein.

### BACKGROUND

### Technical Field

The present disclosure relates to a display device.

### Description of the Related Art

In accordance with advances in information technology, the market for display devices, which are connection media between users and information, is expanding. Accordingly, use of display devices such as light emitting display (LED) devices, quantum dot display (QDD) devices, liquid crystal display (LCD) devices, etc., is increasing.

In such display devices mentioned above, when a scan signal, a data signal, etc., are supplied to sub-pixels formed at a display panel, selected ones of the sub-pixels transmit light therethrough or directly emit light and, as such, an image may be displayed.

The scan signal may be supplied by a gate driver connected to a gate line. The gate driver includes a plurality of stage circuits, and each stage circuit may sequentially supply a scan signal to a plurality of gate lines in a frame period. In accordance with a data signal input correspondingly to the scan signal, an image may be displayed.

Such a gate driver may be disposed in a bezel area which is a non-active area of the display panel.

### BRIEF SUMMARY

The disclosure relates to a display device that includes a gate driver incorporating multiple thin film transistors formed on a shared active layer. This active layer contains alternating doped and undoped regions, enabling dense integration while maintaining electrical isolation between transistors. A continuous undoped region functions as a common channel, and narrower undoped regions positioned between adjacent transistors provide insulation. This structure allows for a reduction in the overall length required to arrange the transistors, resulting in a more compact gate driver layout.

The transistors are connected in parallel with common gate, source, and drain elements, supporting increased current output and faster signal transitions, which are beneficial for high-resolution display performance. The use of low-concentration doped regions between the source or drain and the channel helps improve threshold voltage stability and reduces the impact of short-channel effects. This design is suitable for gate driver circuits formed directly on the display panel, contributing to reduced bezel width and allowing a simplified manufacturing process through selective doping and patterning techniques.

In sum, the present disclosure is directed to a display device that substantially obviates one or more problems due to limitations and disadvantages of the related art.

Various embodiments of the present disclosure provide a display device having a structure capable of reducing the width of a non-active area.

Technical benefits of the present disclosure are not limited to the above-described benefits, and other benefits of the present disclosure not yet described will be more clearly understood by those skilled in the art from the following detailed description.

To achieve these advantages and in accordance with the purpose of the disclosure, as embodied and broadly described herein, a display device includes a substrate, and a gate driver configured to supply a scan signal to a gate line connected to a sub-pixel positioned on the substrate, wherein the gate driver includes a pull-up transistor configured to output the scan signal with a turn-on voltage and a pull-down transistor configured to output the scan signal with a turn-off voltage, and at least one transistor of the pull-up transistor or the pull-down transistor includes a plurality of thin film transistors connected in parallel, wherein the plurality of thin film transistors includes a plurality of source electrodes, a plurality of drain electrodes, a common gate electrode, and a common active layer, wherein the common gate electrode and the common active layer extend in a first direction, wherein the plurality of source electrodes and the plurality of drain electrodes are disposed on the common active layer and spaced apart from the common gate electrode in a second direction crossing the first direction, and wherein the common active layer includes a plurality of doped regions doped with a dopant and a plurality of undoped regions not doped with the dopant, and the plurality of doped regions and the plurality of undoped regions alternate as the common active layer extends in the first direction.

The plurality of undoped regions may include a plurality of first undoped regions extending in the second direction to cross the common gate electrode and spaced apart from one another in the first direction, and a single second undoped region overlapping with the common gate electrode, crossing the plurality of first undoped regions, and extending in the first direction.

The first undoped regions may be positioned in spaces among the plurality of thin film transistors, respectively.

The second undoped region may extend to interconnect the spaces among the plurality of thin film transistors.

The width of the first undoped regions may be smaller than the width of the common gate electrode.

The plurality of first undoped regions may be positioned among the plurality of source electrodes and among the plurality of drain electrodes.

The common active layer may include a common channel region, a plurality of source regions, and a plurality of drain regions, and the common channel region may be positioned in the second undoped region and may extend in the first direction along the common gate electrode.

The common channel region may cross the plurality of first undoped regions.

Each of the plurality of source regions and the plurality of drain regions may be positioned adjacent to the common channel region in the second direction.

The plurality of source regions and the plurality of drain regions arranged in the first direction may be spaced apart from one another in the first direction and insulated from one another by the first undoped regions.

The plurality of source regions and the plurality of drain regions may be positioned in the doped regions, respectively.

Carrier concentrations of the common channel region and the first undoped regions may be lower than the carrier concentration of the doped regions.

The carrier concentrations of the common channel region and the first undoped regions may be equal.

The width of the first undoped regions may be smaller than the width of the common channel region.

A low-concentration doped region having a carrier concentration higher than the carrier concentration of the common channel region, but lower than carrier concentrations of the source regions and the drain regions, may be provided between the common channel region and each of the source regions and between the common channel region and each of the drain regions.

The low-concentration doped region may be positioned outside the common gate electrode.

In accordance with the embodiments of the present disclosure, at least one of the pull-up transistor or the pull-down transistor including the plurality of thin film transistors connected in parallel may include the plurality of source electrodes, the plurality of drain electrodes, the common gate electrode, and the common active layer, and the common active layer may include the plurality of doped regions and the plurality of undoped regions as the common active layer extends in a first direction. As a result, the overall length along which the plurality of thin film transistors connected in parallel is arranged may be reduced. In the present disclosure, accordingly, it may be possible to reduce the width of a non-active area.

In sum, a single continuous active layer serves all parallel thin-film transistors, with alternating doped and undoped regions providing both electrical isolation and a unified conduction path. Narrow undoped strips between neighboring transistors insulate source and drain areas, while a wider undoped region overlapping the shared gate electrode forms a continuous channel across the entire array. By bringing pull up and pull down transistors closer together and summing their channel lengths, this layout both minimizes bezel width and increases total drive current.

Lightly doped transition regions between the heavily doped source and drain areas and the common channel further optimize threshold voltage and carrier flow. In one configuration these lightly doped regions lie beneath the gate overlap to balance parasitic effects, while in another they sit outside the gate overlap to maximize channel width. Both arrangements enhance performance in narrow bezel gate driver displays.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a diagram explaining an example of a display device applicable to the present disclosure;

FIG. 2 is an example explaining configurations of a plurality of shift registers included in a gate driver of FIG. 1;

FIG. 3 is a diagram explaining an equivalent circuit of a shift register shown in FIG. 2;

FIG. 4 is an example of a layout diagram explaining a plurality of thin film transistors according to the present disclosure;

FIG. 5 is an example explaining patterns of doped regions and undoped regions included in a common active layer in FIG. 4;

FIG. 6A is an example explaining a cross-section of each transistor taken along line CS1-CS1 parallel to a second direction in FIG. 4;

FIG. 6B illustrates carrier concentrations of a channel region, a source region, and a drain region provided in a common active layer of a transistor, taken along line CS1-CS1 parallel to a second direction in FIG. 4;

FIG. 7 is an example explaining a cross-section taken along line CS2-CS2 parallel to the second direction in FIG. 4;

FIG. 8A is an example explaining cross-sections taken along lines CS3-CS3 in FIG. FIG. 8B is an example explaining cross-sections taken along lines CS4-CS4 in FIG. 4;

FIG. 9 is an example explaining a cross-section taken along line CS5-CS5 in FIG. 4;

FIGS. 10A, 10B, 10C are views explaining an example of a method of manufacturing the plurality of thin film transistors in accordance with the present disclosure;

FIGS. 11A, 11B are views explaining effects of the plurality of thin film transistors according to the present disclosure;

FIGS. 12A, 12B are views explaining another embodiment of a plurality of thin film transistors according to the present disclosure; and

FIGS. 13A, 13B are views explaining a method of manufacturing the plurality of thin film transistors shown in FIGS. 12A, 12B.

### DETAILED DESCRIPTION

Hereinafter, embodiments will be described with reference to the accompanying drawings.

Throughout the present disclosure, the same reference numerals designate the same constituent elements, respectively.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

It will be understood that, when a constituent element (or a region, a layer, a portion or the like) is referred to as being “on,” “connected to” or “coupled to” another element, it may be directly on, connected or coupled to the other element, or an intervening third element may be present.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “and/or” used herein includes any and all combinations of one or more of configurations associated with one another.

Although terms including an ordinal number, such as first or second, may be used to describe a variety of constituent elements, the constituent elements are not limited to the terms, and the terms are used only for the purpose of discriminating one constituent element from other constituent elements. For example, a first constituent element may be referred to as a second constituent element within the scope of the present disclosure. Similarly, the second constituent element may be referred to as the first constituent element. A component described in a singular form encompasses components in a plural form unless particularly stated otherwise.

Terms such as “under,” “below,” “over” and “above” are used in order to explain associated relations of configurations shown in the drawings. The terms are relative concepts and are described with reference to directions indicated in the drawings. For example, at least one intervening element may be present between two elements unless “immediately” or “directly” is used. It should be understood that terms, such as “below,” “beneath,” “lower,” “above,” “upper,” etc., which are spatially-relative terms, may be used to easily explain associated relations of one device or constituent element with another device or other constituent elements. Accordingly, for example, “below” or “lower” with reference to a first constituent element may encompass a direction opposite to above or upper with reference to the first constituent element.

It should be understood that spatially-relative terms are intended to encompass different orientations of a device when the device is used or operates, in addition to the orientation depicted in the drawings. For example, if a device in one of the drawings is turned over, elements described as being disposed “below” or “beneath” other elements would then be disposed “above” the other elements. The exemplary terms “below” or “beneath” can, therefore, encompass both an orientation of above and below.

It should be understood that the term “comprising,” “including” or the like is intended to express the existence of characteristics, numerals, steps, operations, constituent elements, parts, or a combination thereof, and does not exclude one or more other characteristics, numerals, steps, operations, constituent elements, parts, or combinations thereof, or any addition thereto.

The respective features of various embodiments according to the present disclosure can be partially or entirely joined or combined and technically variably related or operated, and the embodiments can be implemented independently or in combination.

The disclosure proposes packing several parallel thin-film transistors (TFTs) for a gate-driver stage into a single, continuous semiconductor island (e.g., common active layer ACT). Within this shared ACT, lithographically patterned doped regions (DP) and undoped regions (ND) alternate, so each TFT still has its own source, drain, and isolated channel while the “dead space” between etched islands disappears. Because the first undoped regions (ND) are intentionally narrower than the gate width (WG) and the common channel region (CH), adjacent fingers can be spaced more tightly yet still remain isolated, and the full gate aperture lies over undoped material—boosting total channel width and drive current. Optional lightly-doped (LDD) regions can be kept entirely outside the gate to curb short-channel effects. The entire doped/undoped pattern (DP/ND pattern) can be formed with two stripe masks and a single implant step, avoiding extra lithography. The result is a gate-driver strip that sits in the display bezel can be trimmed by roughly 20-30 % (20-30 % shorter in the bezel direction) while delivering higher scan-line charging current—valuable for narrow-border OLED, QLED, and LTPS-LCD panels. The architecture therefore marries layout efficiency with process economy, offering a compact, high-current on-panel gate driver that conventional isolated-island TFT arrays cannot match.

Hereinafter, a display device of the present disclosure will be described with reference to the accompanying drawings and embodiments.

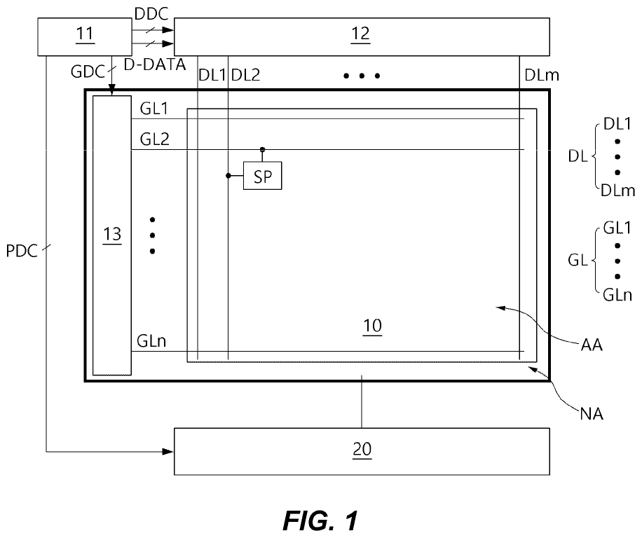

FIG. 1 is a diagram explaining an example of a display device applicable to the present disclosure.

As shown in FIG. 1, a display device according to an embodiment of the present disclosure may include a display panel 10, a timing controller 11, a data driver 12, a gate driver 13, and a power supply 20.

Although the case in which the timing controller 11, the data driver 12, and the power supply 20 are separately provided is shown, as an example, in FIG. 1, a part or all of the timing controller 11, the data driver 12, and the power supply 20 may be integrated into a driving integrated circuit. In FIG. 1, each of the data driver 12, the gate driver 13, and the power supply 20 may include a panel driving circuit configured to drive the display panel 10.

The display panel 10 may include an active area AA and a non-active area NA.

As shown in FIG. 1, the gate driver 13 may be configured in the non-active area NA of the display panel 10 in a gate-driver-in-panel (GIP) manner. For example, the gate driver 13 of the present disclosure may be directly formed on a substrate of the display panel 10.

The active area AA may be an area configured to display an image. A plurality of sub-pixels SP is disposed in the active area AA and, as such, an image may be displayed using the plurality of sub-pixels SP. An area in which the plurality of sub-pixels SP is disposed may become the active area AA, and an area other than the active area AA may become the non-active area NA.

The plurality of sub-pixels SP disposed in the active area AA may display, for example, different colors such as red (R), green (G), and blue (B).

The non-active area NA may be positioned in an edge area surrounding the active area AA. At least one panel driving circuit configured to drive the plurality of sub-pixels SP may be disposed in the non-active area NA.

The timing controller 11 may supply, to the data driver 12, digital image data D-DATA transmitted from a host system (not shown).

The timing controller 11 may receive timing signals, such as a vertical synchronization signal, a horizontal synchronization signal, a data enable signal, a dot clock signal, etc., from the host system and, as such, may generate timing control signals for control of operation timing of the panel driving circuit.

The timing control signals may include a gate timing control signal GDC for control of operation timing of the gate driver 13, a data timing control signal DDC for control of operation timing of the data driver 12, and a power timing control signal PDC for control of operation timing of the power supply 20.

The data driver 12 may be connected to the plurality of sub-pixels SP through data lines DL (DL1 to DLm). The data driver 12 may generate data voltages, which are analog signals required for driving of the plurality of sub-pixels SP, based on the digital image data D-DATA input from the timing controller 11, and may supply the data voltages to the data lines DL.

The data driver 12 may sample and latch the digital image data D-DATA based on the data timing control signal DDC input from the timing controller 11 to convert the digital image data D-DATA into parallel data, may convert the digital image data D-DATA into analog data voltages in accordance with gamma compensation voltages through a digital-analog converter (referred to as a “DAC” hereinafter), and may then supply the analog data voltages to the plurality of sub-pixels SP through the data lines DL, respectively. The analog data voltages may be analog voltage values of different voltage levels corresponding to image grayscales to be expressed at the plurality of sub-pixels SP.

The data driver 12 may output data voltages to the plurality of sub-pixels SP in accordance with the data timing control signal DDC. The data driver 12 may be constituted by a plurality of source driver integrated circuits. Each source driver integrated circuit may include a shift register, a latch, a level shifter, a DAC, and an output buffer.

The gate driver 13 may generate scan signals based on the gate timing control signal GDC, and may supply the scan signals to the plurality of sub-pixels SP through gate lines GL (Gl1 to GLn), respectively. In addition, the gate driver 13 may generate a carry signal CRY to be supplied to a plurality of stages provided in the gate driver 13, for sequential supply of the scan signals.

For example, the gate driver 13 may generate the carry signal CRY based on a carry clock signal supplied from the timing controller 11 as a kind of the gate timing control signal GDC, and may generate the scan signals based on a scan clock signal supplied from the timing controller 11 as a kind of the gate timing control signal GDC.

The power supply 20 may supply a drive voltage for driving of the plurality of sub-pixels SP by processing input power in accordance with the power timing control signal PDC. In addition, the power supply 20 may supply drive power required for operation of the gate driver 13, if necessary.

Meanwhile, the display device according to the embodiment of the present disclosure may include a structure capable of improving the structure of the gate driver 13 to reduce the width of the non-active area NA.

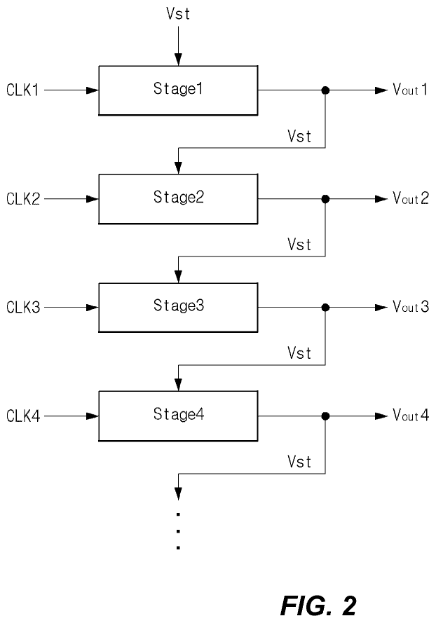

FIG. 2 is an example explaining configurations of a plurality of shift registers included in the gate driver 13 of FIG. 1.

As shown in FIG. 2, the gate driver 13 may include a plurality of stages configured to sequentially output scan signals, for example, scan signals Vout1 to Vout4, to the plurality of gate lines GL1 to GL. Output terminals of the plurality of stages, for example, stages Stage1 to Stage4, may be electrically connected to the plurality of gate lines GL1 to GLn, respectively.

In detail, the first stage Stage1 may start by a separate start signal Vst and may output the first scan signal Vout1 using a first clock signal CLK1.

The second to fourth stages Stage2 to Stage 4 may start by start signals Vst constituted by scan signals Vout1 to Vout3 output from upstream ones thereof, respectively, and may output second to fourth scan signals Vout2 to Vout4 to the second to fourth gate lines GL2 to GL4 using second to fourth clock signals CLK2 to CLK4, respectively.

Meanwhile, although not shown, when a final scan signal Vout is output from a stage at which one frame ends, that is, a final stage, the final stage may receive a reset signal Vreset and, as such, may be initialized. Subsequently, the next frame is begun at the first stage Stage 1. As the first scan signal Vout1 is output from the first stage Stage 1, the above-described procedure may be repeated.

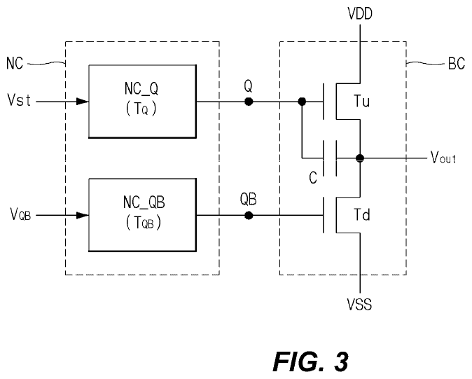

FIG. 3 is a diagram explaining an equivalent circuit of each shift register shown in FIG. 2.

The equivalent circuit shown in FIG. 3 may be an equivalent circuit of one of the plurality of shift registers.

As shown in FIG. 3, the equivalent circuit of each shift register shown in FIG. 2 may include a pull-up node Q, a pull-down node QB, a node controller NC, and a buffer BC.

The buffer BC may include an output terminal of a stage. The buffer BC may include a pull-up transistor Tu, a pull-down transistor Td, and a capacitor C.

The pull-up transistor Tu may be turned on when the pull-up node Q is charged with a gate-high voltage and, as such, may output a scan signal Vout having a turn-on voltage.

The pull-down transistor Td may be turned on when the pull-down node QB is charged with a gate-low voltage and, as such, may output a scan signal Vout having a turn-off voltage.

The capacitor C may function to maintain a turn-on voltage supplied to the pull-up transistor Tu for one frame. The capacitor C may be provided between a gate terminal and a source terminal of the pull-up transistor Tu.

The node controller NC may control charging and discharging of the pull-up node Q and the pull-down node QB. The node controller NC described above may include a pull-up node controller NC_Q configured to control charging and discharging of the pull-up node Q and a pull-down node controller NC_QB configured to control charging and discharging of the pull-down node QB.

The pull-up node controller NC_Q may include at least one transistor TQ for control of the pull-up node Q. The pull-down node controller NC_QB may include at least one transistor TQB for control of the pull-down node QB.

The node controller NC may stably control output of a scan signal Vout. In detail, the node controller NC may discharge the pull-down node QB to a gate-low voltage when the pull-up node Q is charged with a gate-high voltage and may discharge the pull-up node Q to a gate-low voltage when the pull-down node QB is charged with a gate-high voltage.

Accordingly, when a start signal Vst is applied, the pull-up node Q is charged with the gate-high voltage and the pull-down node QB is discharged to the gate-low voltage in accordance with operation of a plurality of transistors TQ and TQB provided at the node controller NC and, as such, the buffer BC may output a high-level voltage VDD as a scan signal Vout.

In addition, when a discharging signal VQB is applied, the pull-up node Q is discharged to the gate-low voltage and the pull-down node QB is charged with the gate-high voltage in accordance with operation of the plurality of transistors TQ and TQB provided at the node controller NC and, as such, the buffer BC may output a low-level voltage VSS as a scan signal Vout.

Meanwhile, at least one transistor of the pull-up transistor Tu or the pull-down transistor Td in the buffer BC of the present disclosure may include a plurality of thin film transistors connected in parallel on a substrate in order to apply high current to a light emitting element provided at each sub-pixel.

For example, in FIG. 3, the pull-up transistor Tu may include a plurality of thin film transistors connected in parallel. In this case, the plurality of thin film transistors connected in parallel may be provided, in common, with a common gate electrode, each drain electrode thereof may be connected to a power source configured to supply the high-level voltage VDD, and each source electrode thereof may be electrically connected to the output terminal of the stage.

Hereinafter, a structure of at least one transistor with a plurality of thin film transistors connected in parallel will be described.

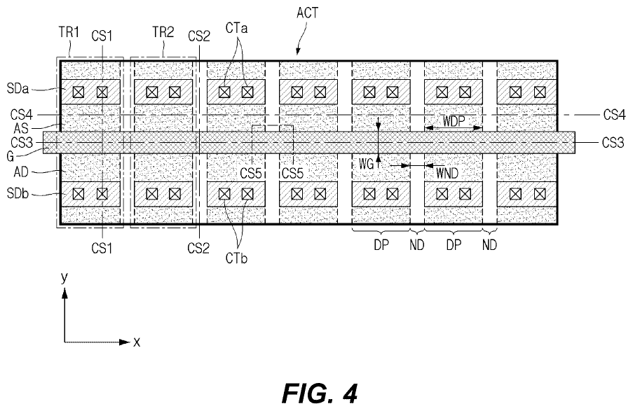

FIG. 4 is an example of a layout diagram explaining a plurality of thin film transistors according to the present disclosure.

Although a plurality of thin film transistors is designated by “TR1” and “TR2” in FIG. 4, for convenience of understanding, the thin film transistors may be disposed in a plurality of doped regions DP arranged to be spaced apart from one another in a first direction x and divided from one another by undoped regions ND extending in a second direction y, respectively. For example, FIG. 4 illustrates the case in which a total of seven thin film transistors, including the thin film transistors TR1 and TR2, is included.

In the following description, the first direction x means a direction identical to an extension direction of a common gate electrode G, and the second direction y means a direction crossing the extension direction of the common gate electrode G.

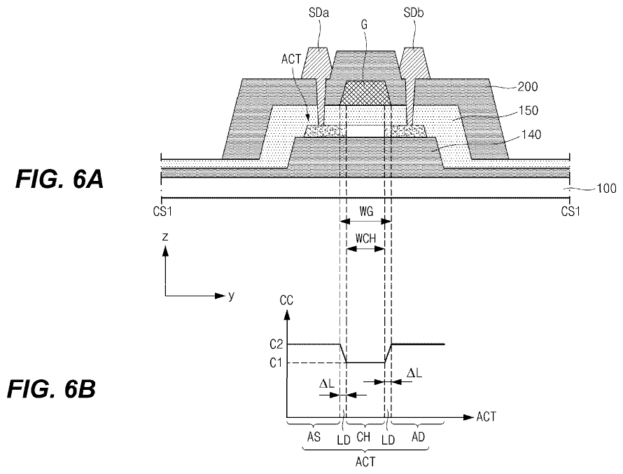

In addition, although a substrate 100, a buffer layer 140, a gate insulating layer 150, and an interlayer insulating layer 200 are omitted from FIG. 4, for convenience of understanding, the following description will be given provided that the substrate 100, the buffer layer 140, the gate insulating layer 150, and the interlayer insulating layer 200 are provided, as shown in FIGS. 6 to 9.

The plurality of thin film transistors shown in FIG. 4 may be used as at least one of the pull-up transistor Tu or the pull-down transistor Td shown in FIG. 3. The plurality of thin film transistors may be connected in parallel on one substrate 100.

For example, when each of the plurality of thin film transistors shown in FIG. 4 is the pull-up transistor Tu of FIG. 3, the common gate electrode G of the plurality of thin film transistors may be electrically connected to pull-up nodes Q in common, a plurality of drain electrodes SDb in the plurality of thin film transistors may be electrically connected in common to a power source configured to supply the high-level voltage VDD of FIG. 3, and a plurality of source electrodes SDa in the plurality of thin film transistors may be electrically connected in common to the output terminal of the stage of FIG. 3.

As shown in FIG. 4, the plurality of thin film transistors may be provided on one substrate 100, and may include the common gate electrode G, a common active layer ACT, the plurality of source electrodes SDa, and the plurality of drain electrodes SDb.

The plurality of source electrodes SDa may be disposed on the common active layer ACT in a state of being spaced apart from the common gate electrode G in the second direction y, and may be spaced apart from one another at portions of the common active layer ACT overlapping with a plurality of undoped regions ND.

The plurality of drain electrodes SDb may be disposed on the common active layer ACT in a state of being spaced apart from the common gate electrode G in the second direction y, and may be spaced apart from one another at the portions of the common active layer ACT overlapping with the plurality of undoped regions ND.

The plurality of source electrodes SDa and the plurality of drain electrodes SDb provided at the plurality of thin film transistors may be disposed on the common active layer ACT, and the source electrode SDa of each thin film transistor may be connected to the common active layer ACT through a contact CTa, and the drain electrode SDb of each thin film transistor may be connected to the common active layer ACT through a contact CTb.

The common gate electrode G may be formed by one common gate electrode extending in the first direction x. That is, the common gate electrode G may be connected in common to the plurality of thin film transistors and may also be disposed in spaces among the plurality of thin film transistors. For example, the common gate electrode G may be constituted by one metal layer without being physically separated in spaces among the thin film transistors (for example, TR1 and TR2).

The common active layer ACT may be formed by one common active layer ACT extending in the first direction x. The common active area ACT may be used in common in the plurality of thin film transistors and may not only overlap with the plurality of thin film transistors, but also may be disposed in spaces among the plurality of thin film transistors.

That is, the common active layer ACT may be constituted by one active layer such that the common active layer ACT may be used in common in the plurality of thin film transistors without being physically separated in spaces among the thin film transistors.

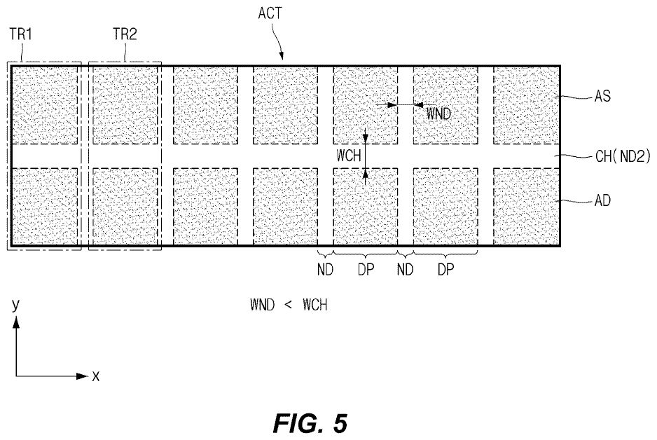

Hereinafter, a pattern structure of the common active layer ACT will be described with reference to FIGS. 4 and 5.

FIG. 5 is an example explaining patterns of doped regions DP and undoped regions ND included in the common active layer ACT in FIG. 4.

As shown in FIGS. 4 and 5, as the common active layer ACT extends in the first direction x, a plurality of doped regions DP and a plurality of undoped regions ND may be alternately repeated. Each doped region DP is a region doped with a dopant, and each undoped region ND may be a dopant-undoped region, that is, a region not doped with a dopant.

The plurality of undoped regions ND may include a plurality of first undoped regions ND and one second undoped region ND2 (CH).

The plurality of first undoped regions ND may be arranged to be spaced apart from one another and may extend in the second direction y to cross the common gate electrode G. The plurality of first undoped regions ND and the plurality doped regions DP may be alternately positioned while extending in the first direction x. Each first undoped region ND may be positioned between adjacent ones of the plurality of thin film transistors, for example, TR1 and TR2. Accordingly, adjacent ones of the plurality of source electrodes SDa and adjacent ones of the drain electrodes SDb may be insulated from each other by corresponding ones of the plurality of first undoped regions ND.

Accordingly, the plurality of first undoped regions ND may divide corresponding ones of the thin film transistors, for example, TR1 and TR2, on the single common active layer ACT by insulating the corresponding thin film transistors, for example, TR1 and TR2, from each other. That is, adjacent ones of the plurality of thin film transistors may be electrically insulated from each other by the plurality of first undoped regions ND.

The single second undoped region ND2 (CH) may extend in the first direction x while overlapping with the common gate electrode G and may cross the plurality of first undoped regions ND. The second undoped region ND2 may extend to interconnect the plurality of thin film transistors, for example, TR1 and TR2. That is, the second undoped region ND2 may not only be positioned to overlap with each of the plurality of thin film transistors, for example, TR1 and TR2, but also may be disposed among the plurality of thin film transistors.

The second undoped region ND2 may be used as a common channel region CH configured to form a channel in the common active layer ACT in accordance with a voltage applied to the common gate electrode G. That is, the second undoped region ND2 may form the common channel region CH. Accordingly, the common channel region CH may cross the plurality of first undoped regions ND.

Since the common channel region CH and the first undoped region ND are not doped with a dopant, carrier concentrations of the common channel region CH and the first undoped region ND may be lower than a carrier concentration of the doped regions DP. For example, carrier concentrations of the common channel region CH and the first undoped region ND (for example, C1 in FIG. 6B) may be equal.

A width WND of the first undoped region ND may be smaller than a width of the common gate electrode G (for example, WG in FIG. 4) or a width WCH of the common channel region CH. In accordance with the present disclosure, it may be possible to reduce the overall length along which the plurality of thin film transistors is arranged in the first direction x by configuring the first undoped region ND such that the width WND of the first undoped region ND is smaller than the width WG of the common gate electrode G or the width WCH of the common channel region CH. Accordingly, it may be possible to reduce the width of the non-active area NA.

Hereinafter, cross-sectional structures of the plurality of thin film transistors shown in FIG. 4 at different positions will be described.

FIGS. 6A and 6B is an example explaining a cross-section of each transistor taken along line CS1-CS1 parallel to the second direction y in FIG. 4.

In detail, FIG. 6A illustrates a cross-sectional structure of each transistor according to the present disclosure, and FIG. 6B illustrates carrier concentrations of a channel region, a source region AS, and a drain region AD provided at the common active layer ACT. In FIG. 6B, an x-axis represents regions of the common active layer ACT, and a y-axis represents a carrier concentration CC.

As shown in FIGS. 6A and 6B, each of the plurality of thin film transistors may include a common active layer ACT, a common gate electrode G, a source electrode SDa, and a drain electrode SDb. A substrate 100 and a buffer layer 140 may be disposed under the common active layer ACT. A gate insulating layer 150 may be disposed between the common gate electrode G and the common active layer ACT. An interlayer insulating layer 200 may be disposed on the common gate electrode G.

As shown in FIGS. 6A and 6B, the common active layer ACT may be disposed on the buffer layer 140, may include an oxide semiconductor, and may be provided with a common channel region CH, and a source region AS, a drain region AD and low-concentration doped regions LD positioned at opposite sides of the common channel region CH in the second direction y.

An oxide semiconductor material included in the common active layer ACT may include at least one of, for example, IZO (InZnO), IGO (InGaO), ITO (InSnO), IGZO (InGaZnO), IGZTO (InGaZnSnO), GZTO (GaZnSnO), GZO (GaZnO), ITZO (InSnZnO), and FIZO (FeInZnO)-based oxide semiconductor materials.

The common channel region CH may be included in the undoped region ND not doped with a dopant. For example, the common channel region CH may be positioned in the second undoped region ND2, and may extend in the first direction x along the common gate electrode G, as described with reference to FIG. 4.

Since the common channel region CH is not doped with a dopant, the common channel region CH may have a lower carrier concentration C1 than those of the source region AS and the drain region AD and may have electrical conductivity corresponding to a voltage applied to the common gate electrode G. In the common channel region CH, a channel, through which carriers move in accordance with the voltage applied to the common gate electrode G, may be formed.

The source region AS and the drain region AD may be positioned in the doped regions DP adjacent to the common channel region CH in the second direction y, respectively, and may be positioned at opposite sides of the common channel region CH, respectively.

The source region AS and the drain region AD may be conductive regions treated to have higher electrical conductivity than that of the common channel region CH through doping with a dopant in a high concentration. The source region AS and the drain region AD may have a higher carrier concentration C2 than that of the common channel region CH in accordance with doping with a dopant in a high concentration.

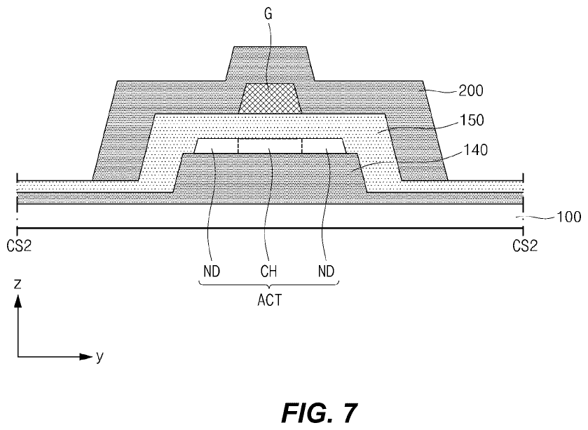

As shown in FIG. 4, a plurality of source regions AS and a plurality of drain regions AD may be positioned in the doping regions DP, respectively, without being positioned in a region overlapping with the first undoped region ND, to be spaced apart from one another in the first direction x. This will be described later with reference to FIG. 7.

Each low-concentration doped region LD, which has a width of ΔL, may be positioned between the common channel region CH and each of the source region AS and the drain region AD. The carrier concentration of the low-concentration doped region LD may be gradually lowered as the low-concentration doped region LD extends from each of the source region AS and the drain region AD toward the common channel region CH. That is, the carrier concentration of the low-concentration doped region LD may be higher than the carrier concentration of the common channel region CH, but lower than the carrier concentrations of the source region AS and the drain region AD.

The common gate electrode G may be disposed on the common active layer ACT to overlap with the common channel region CH and may be spaced apart from the common channel region CH by the gate insulating layer 150. The common gate electrode G may be controlled through a voltage applied thereto to enable a channel to be formed in the common channel region CH of the common active layer ACT.

The common gate electrode G may include a conductive material, and may include, for example, a metal such as aluminum (Al), chromium (Cr), copper (Cu), titanium (Ti), molybdenum (Mo), or tungsten (W).

The source electrode SDa and the drain electrode SDb may be disposed on the interlayer insulating layer 200, and may be spaced apart from the source region AS and the drain region AD, which are the doped regions DP, respectively in a thickness direction z by the interlayer insulating layer 200 and the gate insulating layer 150.

The source electrode SDa and the drain electrode SDb may extend through the interlayer insulating layer 200 and the gate insulating layer 150 at contacts (CTa and CTb in FIG. 4) and, as such, may be electrically connected to the source region AS and the drain region AD, respectively.

The substrate 100 may be formed of a plastic material having flexibility and, as such, may have flexible characteristics. The substrate 100 may also include a thin glass material having flexibility.

The buffer layer 140 may be disposed on the substrate 100 and may include an inorganic insulating material such as silicon oxide (SiO) or silicon nitride (SiN). The buffer layer 140 may insulate the common active layer ACT from a metal layer, such as a shielding pattern (not shown), disposed on the substrate 100.

The gate insulating layer 150 may be disposed between the common gate electrode G and the common active layer ACT to insulate the common gate electrode G and the common active layer ACT from each other. The gate insulting layer 150 may include at least one of silicon oxide (SiOₓ), silicon nitride (SiNₓ), or silicon oxynitride (SiOₓN_{y}). For example, silicon oxide (SiOₓ) may include silicon dioxide (SiO₂).

The interlayer insulating layer 200 may be disposed on the gate insulating layer 150 to cover the common gate electrode G, and may extend along the gate insulating layer 150. The interlayer insulating layer 200 may include an insulating material such as silicon oxide (SiOₓ) or silicon oxynitride (SiOₓN_{y}).

FIG. 7 is an example explaining a cross-section taken along line CS2-CS2 parallel to the second direction y in FIG. 4. In FIG. 4, line CS2-CS2 is positioned in a space among the plurality of thin film transistors, and the configuration shown in FIG. 7 may represent a spatial structure among the plurality of thin film transistors.

As shown in FIG. 7, the common gate electrode G and the common active layer ACT may also be disposed in the space among the plurality of thin film transistors. In addition, the substrate 100, the buffer layer 140, the gate insulating layer 150, and the interlayer insulating layer 200 may also be disposed in the space among the plurality of thin film transistors.

At the common active layer ACT disposed in the space among the plurality of thin film transistors, no doped region DP may be positioned, and each first undoped region ND and the second undoped region ND2, that is, the common channel region CH, may be positioned at the common active layer ACT to contact each other, as shown in FIG. 7.

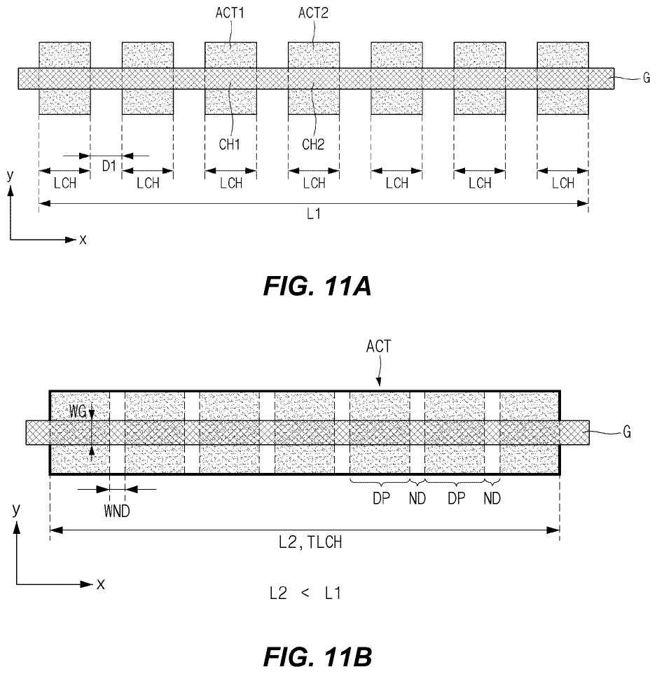

In accordance with the present disclosure, the common channel region CH is also positioned in spaces among the plurality of thin film transistors to divide the plurality of thin film transistors from one another and, as such, it may be possible to increase output current of the entirety of the plurality of thin film transistors and to reduce the overall length along which the plurality of thin film transistors is arranged in the first direction x. Accordingly, the area occupied by the plurality of thin film transistors may be reduced. This will be described in more detail with reference to FIGS. 11A, 11B.

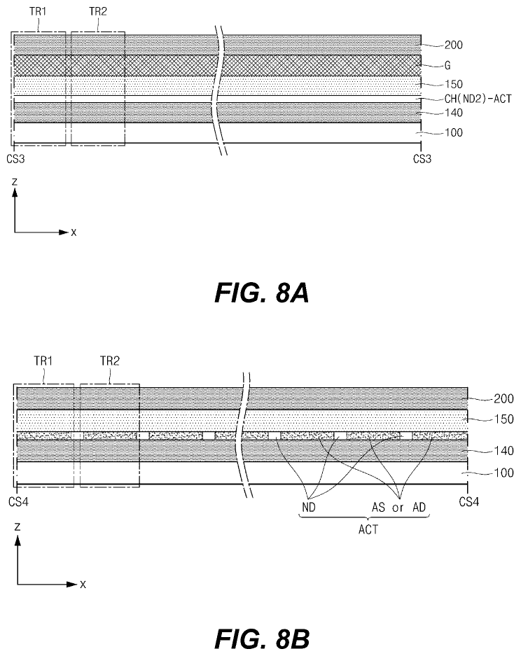

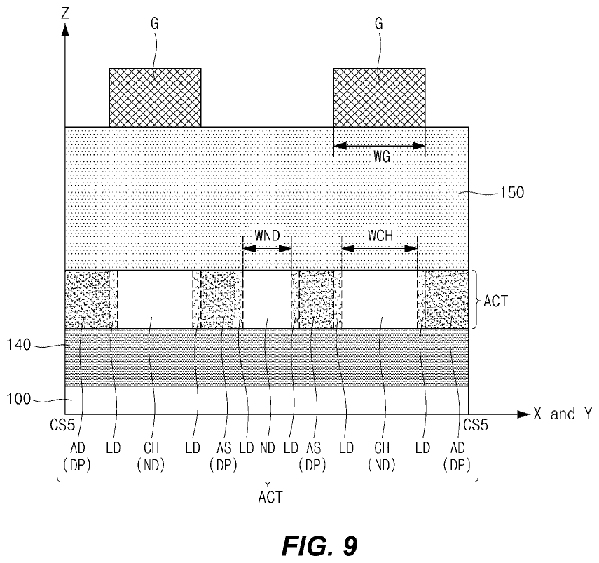

FIGS. 8A and 8B is an example explaining cross-sections taken along lines CS3-CS3 and CS4-CS4 in FIG. 4. FIG. 9 is an example explaining a cross-section taken along line CS5-CS5 in FIG. 4.

FIG. 8A illustrates a cross-section taken along the common gate electrode G extending in the first direction x.

As shown in FIG. 8A, each of the common gate electrode G and the common channel region CH (that is, the second undoped region ND2) may be configured to extend in the first direction x and, as such, to have a single structure throughout the entirety of the plurality of thin film transistors. That is, each of the common gate electrode G and the common channel region CH may also be positioned between adjacent ones of the thin film transistors (for example, TR1 and TR2).

In addition, the substrate 100, the buffer layer 140, the gate insulating layer 150, and the interlayer insulating layer 200 may also be disposed in spaces among the plurality of thin film transistors.

FIG. 8B illustrates a cross-section taken in the first direction x between the common gate electrode G and the source electrode SDa of each thin film transistor. The cross-section taken in the first direction x between the common gate electrode G and the drain electrode SDb of each thin film transistor TR1 or TR2 may be identical to the cross-section of FIG. 8B.

As shown in FIG. 8B, the source region AS (or the drain region AD) and the first undoped region ND may be alternately repeated in the cross-section of the common active layer ACT taken in the first direction x between the common gate electrode G and the source electrode SDa of each thin film transistor. As shown in FIG. 8B, the first undoped region ND may be positioned in the space between adjacent ones of the plurality of thin film transistors and, as such, may insulate the source regions AS (or the drain regions AD) of the adjacent ones of the thin film transistors.

As shown in FIG. 9, in accordance with the cross-section taken along line CS5-CS5 in FIG. 4, the width WND of the first undoped region ND positioned between the adjacent thin film transistors may be smaller than the width WG of the common gate electrode G and may be smaller than the width WCH of the common channel region CH.

For reference, although the interlayer insulating layer 200 over the common gate electrode G and the gate insulating layer 150 may be omitted from FIG. 9, for convenience of understanding, the interlayer insulating layer 200 may be provided as described with reference to FIGS. 6 to 8.

In accordance with the present disclosure, it may be possible to reduce the distance between adjacent ones of the thin film transistors by electrically isolating adjacent ones of the plurality of thin film transistors from each other by the first undoped region ND under the condition that the plurality of thin film transistors uses the single common active layer ACT. Accordingly, it may be possible to reduce the length along which the plurality of thin film transistors is arranged in the first direction x and, as such, to reduce the width of the non-active area NA.

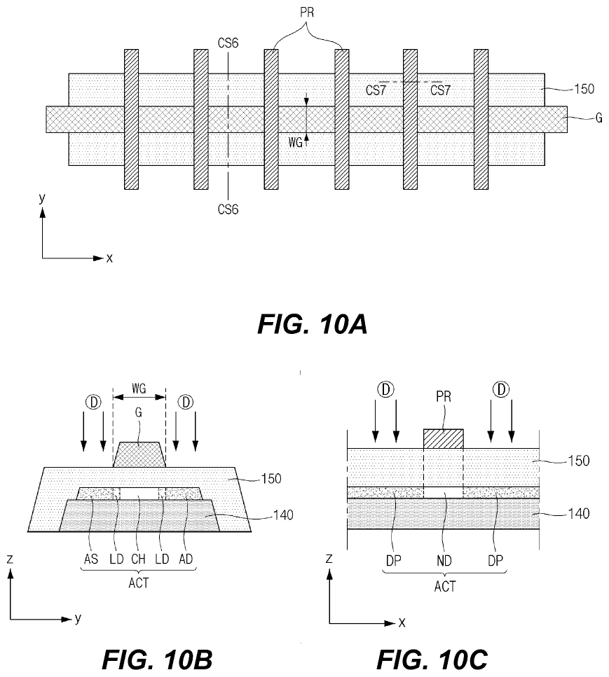

FIGS. 10A, 10B, 10C is a view explaining an example of a method of manufacturing the plurality of thin film transistors in accordance with the present disclosure.

FIG. 10A shows a state in which a photoresist PR has been patterned on the gate insulating layer 150 and the common gate electrode G under the condition that the substrate 100, the buffer layer 140, the common active layer ACT in an undoped state, the gate insulating layer 150 and the common gate electrode G have been formed. The photoresist PR may be patterned such that patterns thereof are spaced apart from one another in a first direction x and extend in a second direction y.

The photoresist PR extending in the second direction y may be patterned to have a smaller width than the width WG of the common gate electrode G. After patterning of the photoresist PR, a dopant D may be implanted in the common active layer ACT from an upper side of the gate insulating layer 150, as shown in FIGS. 10B and 10C. FIG. 10B shows a cross-section taken along line CS6-CS6 in FIG. 10A, and FIG. 10C shows a cross-section taken along line CS7-CS7 in FIG. 10A.

For example, as shown in FIG. 10B, the dopant D may be implanted in the common active layer ACT at an outside of the common gate electrode G from an upper side. Portions of the common active layer ACT doped with the dopant D may be formed into doped regions DP, respectively, and a portion of the common active layer ACT prevented from being doped with the dopant D by the common gate electrode G may be formed into a second undoped region ND2. Thereafter, a subsequent thermal treatment process for formation of the interlayer insulating layer 200, etc. may be performed.

Accordingly, the doped region DP positioned in the common active layer ACT at one side of the common gate electrode G in the second direction y may be treated to have conductivity and, as such, may be formed into a source region AS, whereas the doped region DP positioned in the common active layer ACT at the other side of the common gate electrode G in the second direction y may be treated to have conductivity and, as such, may be formed into a drain region AD.

In addition, hydrogen contained in the source region AS and the drain region AD may be diffused into an inside of the common gate electrode G in the subsequent thermal treatment process and, as such, low-concentration doped regions LD may be formed. Furthermore, the second undoped region ND2 formed in the common active layer ACT through prevention of doping with the dopant D by the common gate electrode G may be formed into a common channel region CH.

In addition, as shown in FIG. 10C, a portion of the common active layer ACT overlapping with the photoresist PR is prevented from being doped with the dopant D and, as such, may be formed into a first undoped region ND, whereas portions of the common active layer ACT at opposite sides of the photoresist PR in the first direction x may be formed into a source region AS or a drain region AD. Although not shown in FIG. 10C, a low-concentration doped region LD may be formed between each doped region DP and the first undoped region ND, as shown in FIG. 10B.

In accordance with the present disclosure, it may be possible to reduce the overall length along which the plurality of transistors is arranged in the first direction x by providing a structure configured to insulate a plurality of source regions AS respectively provided at the plurality of transistors from one another by the first undoped region ND and to insulate a plurality of drain regions AD respectively provided at the plurality of transistors from one another by the first undoped region ND, as described above.

FIGS. 11A, 11B is a view explaining effects of the plurality of thin film transistors according to the present disclosure.

FIG. 11A illustrates a comparative example in which a plurality of thin film transistors is connected in parallel through a common gate electrode G and active layers (for example, ACT1 and ACT2) respectively provided at the plurality of thin film transistors are spaced apart from one another in a first direction x, whereas FIG. 11B illustrates an example in which a common active layer ACT is used in a plurality of thin film transistors in accordance with the present disclosure.

Although a substrate 100, a buffer layer 140, a gate insulating layer 150, and an interlayer insulating layer 200 are not shown in FIGS. 11A, 11B, for convenience of understanding, the following description will be given provided that the substrate 100, the buffer layer 140, the gate insulating layer 150, and the interlayer insulating layer 200 are provided.

When active layers (for example, ACT1 and ACT2) of a plurality of thin film transistors are physically and spatially spaced apart from one another, as in the comparative example shown in FIG. 11A, each of the substrate 100, the buffer layer 140, the gate insulating layer 150, and the interlayer insulating layer 200 inevitably has portions physically and spatially spaced apart from one another, similarly to the active layers (for example, ACT1 and ACT2), in the plurality of thin film transistors. Accordingly, there is a limitation in reducing a distance D1 among the plurality of thin film transistors.

As a result, in the comparative example, the distance D1 among the plurality of thin film transistors may be greater than a width WG of a gate electrode G and, as such, an overall length L1 along which the plurality of thin film transistors is arranged may be longer than an overall length L2 of the plurality of thin film transistors of the present disclosure according to FIG. 11B.

However, as shown in FIG. 11B, a common active layer ACT is used in the present disclosure and, as such, it is unnecessary for each of the substrate 100, the buffer layer 140, the gate insulating layer 150, and the interlayer insulting layer 200 to have portions physically and spatially spaced apart from one another. In addition, first undoped regions ND are formed in the common active layer ACT such that the first undoped regions ND are spaced apart from one another by a predetermined distance, and the plurality of thin film transistors is insulated from one another by the first undoped regions ND. Accordingly, the whole thin film transistor arrangement length L2 may be relatively small.

In accordance with the present disclosure, each first undoped region ND positioned among the plurality of thin film transistors may be formed to have a width WND smaller than the width WG of the common gate electrode G by patterning the photoresist PR to have a smaller width than the width WG of the common gate electrode G. Accordingly, the distance WND among the plurality of thin film transistors in the present disclosure may be smaller than the distance D1 of the comparative example. Thus, the overall length L2 along which the plurality of thin film transistors in the present disclosure is arranged in the first direction x may be smaller than the overall length L1 of the comparative example.

In addition, in the comparative example of FIG. 11A, the active layers ACT1 and ACT2 are not provided in the spaces D1 among the plurality of thin film transistors and, as such, the channel region in each of the plurality of thin film transistors may be formed only in a region in which each of the active layers ACT1 and ACT2 overlaps with the gate electrode G, and may have a length of LCH. As a result, in the comparative example, a sum of lengths of all channel regions formed in the entirety of the plurality of thin film transistors (LCH*7) is inevitably smaller than the overall arrangement length L1 of the plurality of thin film transistors.

However, in the present disclosure as in FIG. 11B, a common channel region CH is provided even in spaces among the plurality of thin film transistors and, as such, the total length, TLCH, of channel regions formed at respective thin film transistors may be increased to the whole arrangement length L2 of the thin film transistors. Accordingly, output current of the entirety of the plurality of thin film transistors may be further increased. That is, the present disclosure may use the space among the thin film transistor as a channel region and, as such, may enhance the efficiency of the plurality of thin film transistors.

Meanwhile, although the case in which the low-concentration doped regions LD are positioned inside the common gate electrode G has been described, as an example, in FIGS. 4 to 11, the present disclosure is not limited thereto. For example, in the present disclosure, it may be possible to dispose the low-concentration doped regions LD outside the common gate electrode G in order to maximize the width WCH of the common channel region CH provided inside the common gate electrode G. This will be described hereinafter.

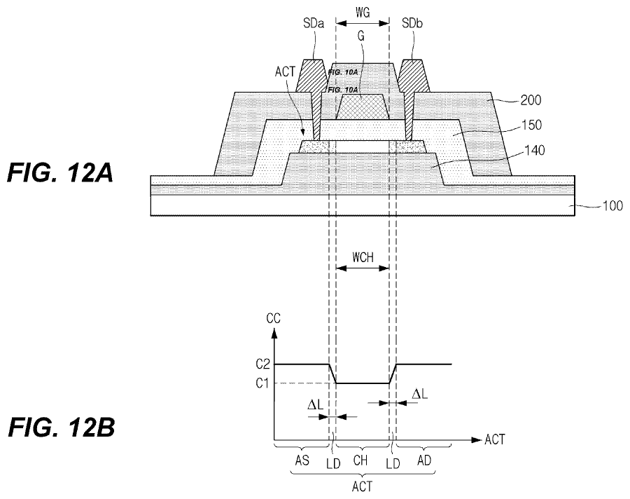

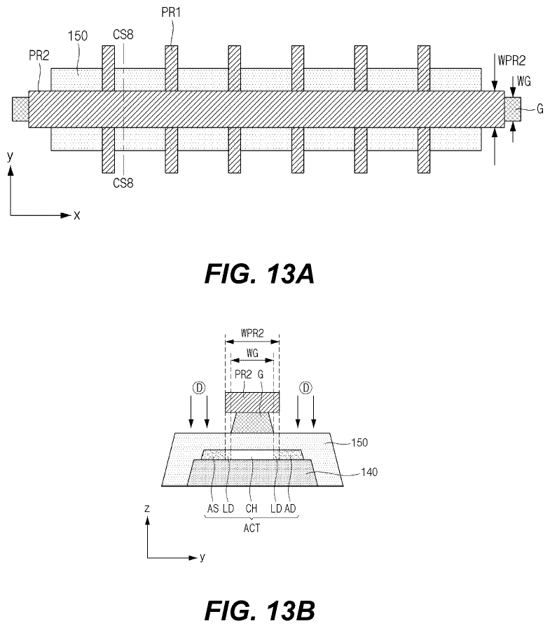

FIGS. 12A, 12B is a view explaining another embodiment of a plurality of thin film transistors according to the present disclosure. FIGS. 13A, 13B is a view explaining a method of manufacturing the plurality of thin film transistors shown in FIGS. 12A, 12B.

The structure of the thin film transistor shown in FIGS. 12A, 12B may be applied in common to the plurality of thin film transistors shown in FIG. 4.

As shown in FIGS. 12A and 12B, in the thin film transistor according to the other example of the present disclosure, the low-concentration doped region LD may be positioned to have a width of L at an outside of the common gate electrode G. In the present disclosure, accordingly, it may be possible to maximize the width WCH of the common channel region CH to a level substantially equal to the width WG of the common gate electrode G.

In accordance with the present disclosure, as the width WCH of the common channel region CH is maximized, it may be possible to reduce a phenomenon in which a threshold voltage Vth of the entirety of the plurality of thin film transistors connected in parallel shifts negatively due to a short channel.

FIG. 13A is a plan view explaining a method of manufacturing the plurality of thin film transistors shown in FIGS. 12A and 12B. FIG. 13B is a cross-sectional view taken along line CS8-CS8 in FIG. 13A.

In accordance with the present disclosure, in order to manufacture the plurality of thin film transistors connected in parallel, a first photoresist PR1 and a second photoresist PR2 may be patterned on the gate insulating layer 150 and the common gate electrode G, as shown in FIG. 13A.

In accordance with the present disclosure, the first photoresist PR1 may be patterned to extend in a first direction x crossing the common gate electrode G, and the second photoresist PR2 having a greater width WPR2 than the width WG of the common gate electrode G may be additionally patterned to extend in the first direction x on the common gate electrode G.

Thereafter, as shown in FIG. 13B, in a dopant implantation process, a dopant D may be implanted. In detail, the dopant D may be implanted in the active layer ACT through the gate insulating layer 150 exposed at an outside of the first photoresist PR1 and the second photoresist PR2. Thereafter, a subsequent thermal treatment process may be performed.

Doped regions DP formed in the active area ACT through implantation of the dopant D may be treated to have conductivity and, as such, may be formed into a source region AS or a drain region AD. A part of hydrogen contained in the source region AS or the drain region AD may move toward the common gate electrode G during the subsequent thermal treatment process and, as such, a low-con centration doped region LD may be formed.

In this case, the low-concentration doped region LD may be formed at an outside of the common gate electrode G due to a limited movement distance of hydrogen, and the common channel region CH formed under the common gate electrode G may have a width equal to the width WG of the common gate electrode G.

Accordingly, in the plurality of thin film transistors according to the other example of the present disclosure, it may be possible to reduce the phenomenon in which the threshold voltage Vth of the entirety of the plurality of thin film transistors connected in parallel shifts negatively, by maximizing the width WCH of the common channel region CH.

As apparent from the above description, in the embodiments of the present disclosure, at least one transistor of the pull-up transistor Tu or the pull-down transistor Td including the plurality of thin film transistors connected in parallel may include the common active layer ACT, and the common active layer ACT may include the plurality of doped regions DP and the plurality of undoped regions ND as the common active layer ACT extends in the first direction x. As a result, the overall length along which the plurality of thin film transistors connected in parallel is arranged may be reduced. In the present disclosure, accordingly, it may be possible to reduce the width of the non-active area NA.

Various embodiments of the display device employs a single, continuous semiconductive film (“common active layer”) that extends across both the active display region and the adjacent non-active bezel region of the display panel. This common active layer is doped in a repeating pattern of source/drain regions and undoped regions along a first (row-wise) direction. A continuous gate electrode overlies the active layer and likewise extends in that first direction. Source and drain electrodes are formed on the active layer on either side of the gate electrode in a second (column-wise) direction, such that a plurality of thin-film transistors are defined in parallel along the first direction. Each doped region serves as the source or drain of one transistor, and the undoped regions interrupt electrical continuity between adjacent source/drain doped regions except where intended to form the channel. Because the channel-forming region is itself undoped and overlaps the gate electrode, a continuous channel extends beneath the gate across all parallel transistors, while the narrow undoped strips between doped regions serve to isolate each transistor's source and drain from its neighbors.

In one embodiment, the common active layer spans substantially the full width of the non-active bezel area, so that the same layer used to form the array of sub-pixel drive transistors also provides a uniform overlay under the bezel. By configuring the width of the common active layer in the first direction to correspond substantially to the bezel width, the thickness of the bezel can be minimized without adding masking steps or interrupting the layer continuity. Mask openings in the non-active area are used to define contact regions or dummy structures, but no extra layer patterning is required solely for bezel definition.

To further optimize device performance, the patterning of the common active layer may include lightly-doped transition regions between each heavily-doped source/drain region and the central undoped channel region. These lightly-doped regions may be formed either beneath the gate overlap or outside the gate overlap, depending on the desired trade-off between drive current and threshold stability. The isolation strips (e.g., first undoped regions) are deliberately made narrower than the gate electrode width to minimize inactive spacing, while the continuous channel region (e.g., second undoped region) spans at least the full extent of the gate projection. Together, these features allow the aggregate channel length of the multi-finger transistor to equal the sum of the individual finger lengths, thereby increasing total drive current without increasing the transistor footprint. Those skilled in the art will appreciate, through the above-described content, that various modifications, additions and substitutions are possible, without departing from the scope and spirit of the disclosure. Therefore, the technical scope of the present disclosure should be defined by the appended claims without being limited to the content described in the detailed description of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate; and
a gate driver configured to supply a scan signal to a gate line connected to a sub-pixel positioned on the substrate,
wherein the gate driver comprises a pull-up transistor configured to output the scan signal with a turn-on voltage and a pull-down transistor configured to output the scan signal with a turn-off voltage, and at least one transistor of the pull-up transistor or the pull-down transistor comprises a plurality of thin film transistors connected in parallel,
wherein the plurality of thin film transistors comprises a plurality of source electrodes, a plurality of drain electrodes, a common gate electrode, and a common active layer,
wherein the common gate electrode and the common active layer extend in a first direction,
wherein the plurality of source electrodes and the plurality of drain electrodes are disposed on the common active layer and spaced apart from the common gate electrode in a second direction crossing the first direction, and
wherein the common active layer comprises a plurality of doped regions doped with a dopant and a plurality of undoped regions lacking the dopant, and the plurality of doped regions and the plurality of undoped regions alternate as the common active layer extends in the first direction.

2. The display device according to claim 1, wherein the plurality of undoped regions comprises:
a plurality of first undoped regions extending in the second direction to cross the common gate electrode and spaced apart from one another in the first direction; and
a second undoped region configured to overlap with the common gate electrode, crossing the plurality of first undoped regions, and extending in the first direction.

3. The display device according to claim 2, wherein the first undoped regions are positioned in spaces among the plurality of thin film transistors, respectively.

4. The display device according to claim 2, wherein the second undoped region extends to interconnect the spaces among the plurality of thin film transistors.

5. The display device according to claim 2, wherein a width of the first undoped regions is smaller than a width of the common gate electrode.

6. The display device according to claim 2, wherein the plurality of first undoped regions is positioned among the plurality of source electrodes and is positioned among the plurality of drain electrodes.

7. The display device according to claim 2, wherein:
the common active layer comprises a common channel region, a plurality of source regions, and a plurality of drain regions; and
the common channel region is positioned in the second undoped region and extends in the first direction along the common gate electrode.

8. The display device according to claim 7, wherein the common channel region crosses the plurality of first undoped regions, and wherein the common channel region under each of the plurality of thin film transistors is electrically isolated by the plurality of first undoped regions, during operation.

9. The display device according to claim 7, wherein each of the plurality of source regions and the plurality of drain regions is positioned adjacent to the common channel region in the second direction,
wherein the plurality of source regions and the plurality of drain regions arranged in the first direction are spaced apart from one another in the first direction and electrically isolated from one another by the first undoped regions, and
wherein the plurality of source regions and the plurality of drain regions are positioned in the doped regions, respectively.

10. The display device according to claim 7, wherein carrier concentrations of the common channel region and the first undoped regions are lower than a carrier concentration of the doped regions, and
wherein the carrier concentrations of the common channel region and the first undoped regions are either equal or substantially equal.

11. The display device according to claim 7, wherein each of the first undoped regions has a width in the first direction that is smaller than a width in the second direction of the common channel region.

12. The display device according to claim 7, wherein a low-concentration doped region having a carrier concentration higher than a carrier concentration of the common channel region, but lower than carrier concentrations of the source regions and the drain regions is provided between the common channel region and each of the source regions and between the common channel region and each of the drain regions, and
wherein the low-concentration doped region is positioned outside the common gate electrode.

13. A display device comprising:
a substrate defining an active area and a non-active area adjacent to the active area;
a plurality of sub-pixels on the substrate;
a common active layer on the substrate;
a common gate electrode extending along a first direction and on the common active layer;
a plurality of source electrodes and a plurality of drain electrodes are on the common active layer;
wherein the plurality of source electrodes and the plurality of drain electrodes are spaced apart from the common gate electrode in a second direction transverse to the first direction and arranged in parallel in the first direction, and
wherein the common active layer comprises a plurality of doped regions doped with a dopant and a plurality of undoped regions lacking the dopant, and the plurality of doped regions and the plurality of undoped regions alternate as the common active layer extends in the first direction.

14. The display device according to claim 13, wherein the non-active area is positioned in an edge area surrounding the active area, and
wherein a width in the first direction of the common active layer is configured to correspond substantially to a width in the first direction of the non-active area.

15. A display device comprising:
a substrate having an active area and an adjacent non-active area;
a common active layer on a substrate,
a plurality of thin film transistors, each transistor including a source region and a drain region;
a gate electrode extending in a first direction overlapped by the common active layer;
alternating doped regions and undoped regions formed in the common active layer along the first direction such that adjacent thin film transistors of the plurality of thin film transistors share the common active layer without electrical continuity between their source and drain regions; and
wherein the undoped regions include a plurality of first undoped strips each located between adjacent source and drain regions to provide electrical isolation, and a second undoped region overlapping the gate electrode to form a continuous channel across all of the plurality of thin film transistors.

16. The display device of claim 15, wherein each of the first undoped strips extends in a second direction perpendicular to the first direction, each of the first undoped strips has a width less than a width of the gate electrode, and
the second undoped region extends continuously along the first direction across all of the first undoped strips.

17. The display device of claim 15, further comprising lightly doped transition regions between the doped regions and the second undoped region,
wherein the lightly doped transition regions are positioned beneath the gate electrode overlap,
the lightly doped transition regions are positioned outside the overlap of the gate electrode.

18. The display device of claim 15, wherein the plurality of thin film transistors include pull up transistors and pull down transistors arranged in parallel and sharing the common active layer.

19. The display device of claim 16, wherein the continuous channel extends in the first direction across the entire non-active area.

20. The display device of claim 16, wherein the first undoped strips and the second undoped region together define a continuous conduction path overlapping the gate electrode, the continuous conduction path having an aggregate channel length equal to a sum of channel lengths across the plurality of thin film transistors, thereby, in operation, increasing total drive current.
